(19) United States
(12) Patent Application Publication
(10) Pub. No.: US 2009/0309767 A1
(43) Pub. Date: Dec. 17, 2009

(54) EXTENDIBLE KEYPAD MODULE AND MOBILE TERMINAL HAVING THE SAME

(75) Inventors: Seon Hee SHIM, Suwon-si (KR); Jae Chul JIN, Hwaseong-si (KR); Young Ki KIM, Seongnam-si (KR); Ki Taek KIM, Yongin-si (KR)

Correspondence Address: THE FARRELL LAW FIRM, LLP, 290 Broadhollow Road, Suite 210E, Melville, NY, 11747, US

(73) Assignee: SAMSUNG ELECTRONICS CO., LTD., Suwon-si (KR)

(21) Appl. No.: 12/482,865

(22) Filed: Jun. 11, 2009

(30) Foreign Application Priority Data
Jun. 12, 2008 (KR) 0054947/2008

(51) Int. Cl. H03M 11/00

(52) U.S. Cl. 341/22

(57) ABSTRACT

An extendible keypad module and a mobile terminal having the same are provided. The keypad module includes a plurality of key supports for mounting keys; a guide unit for housing the plurality of key supports; a driver for moving to the inside and the outside of the guide unit at one side of the guide unit; and a link for connecting the driver and the plurality of key supports, wherein gaps between the plurality of key supports are changed by movement of the driver. Thereby, when using a mobile terminal, gaps between keys can be widened and thus the keys can be more conveniently input. Further, by adjusting locations of coupling protrusions formed in a link, gaps between the keys can be adjusted.

### PRIORITY

This application claims priority to an application entitled “EXTENDIBLE KEYPAD MODULE AND MOBILE TERMINAL HAVING THE SAME” filed in the Korean Intellectual Property Office on Jun. 12, 2008 and assigned Serial No. 10-2008-0054947, the contents of which are incorporated herein by reference.

### BACKGROUND OF THE INVENTION

1. Field of the Invention

The present invention relates to a keypad module and a mobile terminal having the same, and more particularly, to a keypad module and a mobile terminal having the same that can change gaps between keys mounted in the keypad module.

2. Description of the Related Art

In general, a mobile terminal is an electronic device with which a user can freely communicate almost regardless of time and location. The mobile terminal has developed to perform functions such as Internet connection and digital broadcasting reception as well as a communication function. Further, functions such as document writing and a game player have typically been added to the mobile terminal. When the user uses such other functions of the mobile terminal, the number of key inputs increases.

The mobile terminal has a small size for convenience of carrying. As the size of the mobile terminal is decreased, the size of keys provided in the mobile terminal decreases accordingly, and gaps between the keys also decrease. Accordingly, the user experiences inconvenience when trying to input keys provided in the mobile terminal. However, if such inconvenience is solved by increasing the size of the keys or by widening gaps between the keys, the size of the mobile terminal inevitably increases.

### SUMMARY OF THE INVENTION

Therefore, a mobile terminal in which gaps between the keys become narrow when the mobile terminal is not used and become wide when the mobile terminal is used is needed. Further, if gaps between the keys are irregular, the user experiences an inconvenience in inputting keys and thus there is a need to move the keys while uniformly sustaining gaps between the keys.

The present invention has been made in view of at least the above problems, and provides a keypad module and a mobile terminal having the same that can extend gaps between keys.

The present invention further provides a keypad module and a mobile terminal having the same that can uniformly sustain gaps between keys provided in the keypad module when widening gaps between the keys.

In accordance with an aspect of the present invention, a keypad module includes a plurality of key supports for mounting keys; a guide unit for housing the plurality of key supports; a driver for moving to the inside and the outside of the guide unit at one side of the guide unit; and a link for connecting the driver and the plurality of key supports, wherein gaps between the plurality of key supports are changed by movement of the driver.

In accordance with another aspect of the present invention, a keypad module includes a plurality of key supports for mounting keys; a guide unit for housing the plurality of key supports; a first driver for moving to the inside and the outside of the guide unit at a first side of the guide unit; a second driver for moving to the inside and the outside of the guide unit at a second side of the guide unit opposite to the first side; a first link for connecting the first driver and at least one of the plurality of key supports; and a second link for connecting the second driver and the key supports not connected with the first link, wherein gaps between the plurality of key supports are changed by movement of the first driver and the second driver.

In accordance with another aspect of the present invention, a keypad module includes a plurality of key supports for housing keys, each key support having a coupling hole; a guide unit for housing the plurality of key supports; a guide panel fixed to the guide unit and having moving holes at opposite ends; a first link having one end connected to the moving hole formed at one end of the guide panel and connected to a coupling hole of at least one of the plurality of key supports through a coupling protrusion formed on the first link; and a second link having one end connected to the moving hole formed at the end of the guide panel opposite to the end connected to the first link, and the other end connected to the first link, and connected to a coupling hole of the key supports not connected with the first link through a coupling protrusion formed on the second link, wherein the plurality of key supports move on the guide panel.

In accordance with another aspect of the present invention, a mobile terminal includes a keypad module including a plurality of key supports for mounting keys, a guide unit for housing the plurality of key supports, a driver for moving to the inside and the outside of the guide unit at one side of the guide 1o unit, and a link for connecting the driver and the plurality of key supports; a fixed case for mounting the guide unit; and a moving case movably coupled to the fixed case for enclosing the outside of the driver, wherein gaps between the plurality of key supports are changed by movement of the moving case.

In accordance with another aspect of the present invention, a mobile terminal includes a keypad module including a plurality of key supports for mounting keys, a guide unit for housing the plurality of key supports, a first driver for moving to the inside and the outside of the guide unit at a first side of the guide unit, a second driver for moving to the inside and the outside of the guide unit at a second side of the guide unit opposite to the first side, a first link for connecting the first driver and at least one of the plurality of key supports, and a second link for connecting the second driver and the key supports not connected with the first link; a fixed case for mounting the guide unit; and a first moving case and a second moving case movably coupled to the fixed case for enclosing the outside of the first driver and the second driver, respectively, wherein gaps between the plurality of key supports are changed by movement of the first moving case and the second moving case.

### BRIEF DESCRIPTION OF THE DRAWINGS

The objects, features and advantages of the present invention will be more apparent from the following detailed description in conjunction with the accompanying drawings, in which:

FIG. 1 are perspective views illustrating a mobile terminal according to an exemplary embodiment of the present invention;

FIG. 2 is a perspective view illustrating keys, a flexible PCB, and a key support of the mobile terminal of FIG. 1;

FIG. 3 are perspective views illustrating links for coupling to the key support of FIG. 2;

FIG. 4 are plan views illustrating a keypad module according to another exemplary embodiment of the present invention;

FIG. 5 are plan views illustrating a keypad module according to another exemplary embodiment of the present invention;

FIG. 6 are plan views illustrating a keypad module according to another exemplary embodiment of the present invention;

FIG. 7 is a perspective view illustrating a guide panel of a keypad module according to another exemplary embodiment of the present invention; and

FIG. 8 are plan views illustrating a keypad module having the guide panel of FIG. 7.

### DETAILED DESCRIPTION OF EXEMPLARY EMBODIMENTS

Hereinafter, embodiments of the present invention are described in detail with reference to the accompanying drawings. The same reference numbers are used throughout the drawings to refer to the same or like parts. The views in the drawings are schematic views only, and are not intended to be to scale or correctly proportioned. Detailed descriptions of well-known functions and structures incorporated herein may be omitted to avoid obscuring the subject matter of the present invention.

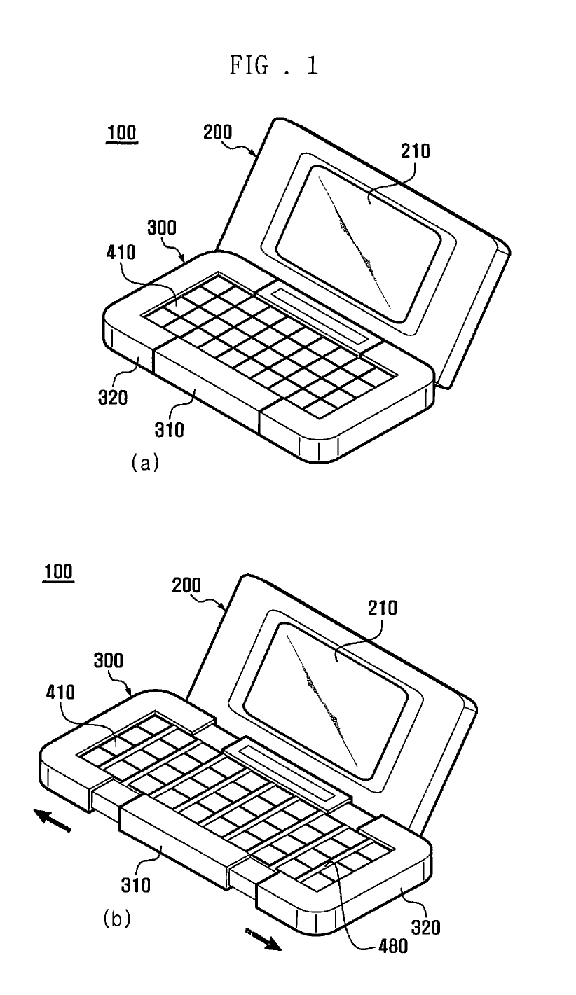

Diagrams (a) and (b) of FIG. 1 are perspective views illustrating a mobile terminal according to an exemplary embodiment of the present invention.

Referring to FIG. 1, a mobile terminal 100 according to an exemplary embodiment of the present invention is a folder type mobile terminal, however a mobile terminal according to the present invention is not limited to a folder type. The mobile terminal 100 includes a folder unit 200 and a main body 300. The folder unit 200 includes a display unit 210. The main body 300 includes a fixed case 310, a moving case 320, and keys 410. The keys 410 are mounted in the fixed case 310. The moving case 320 is movably coupled to the fixed case 310. In the present embodiment, two moving cases 320 are coupled to opposite side surfaces of the fixed case 310, however one moving case or three moving cases may be coupled to the fixed case 310.

When using the mobile terminal 100, by opening the folder unit 200, the display unit 210 is exposed to the outside. The fixed case 310 and the moving case 320 are coupled to each other, as shown in diagram (a) of FIG. 1. A user can manipulate the mobile terminal 100 by inputting the keys 410. However, in this state, because gaps between the keys 410 are narrow, the user experiences inconvenience in inputting the keys 410.

In order for the user to conveniently input the keys 410, the user moves the moving case 320 in a direction away from the fixed case 310, as shown in diagram (b) of FIG. 1. By moving the moving case 320 in this way, the gaps between the keys 410 are widened. Therefore, the user can conveniently input the keys 410.

In the present embodiment, the mobile terminal 100 may include Light Emitting Diodes (LEDs) 480 positioned at a lower part of the keys 410. As the moving case 320 moves, the gaps between the keys 410 are widened, and the LEDs 480 can illuminate to the outside through the gaps. Therefore, the keys 410 can be easily input at a dark location, and the mobile terminal 100 has an improved design.

When use of the mobile terminal 100 is terminated, the user moves the moving case 320 in a direction towards the fixed case 310 to couple thereto. By moving the moving case 320 in this way, gaps between the keys 410 are narrowed. Thereafter, by closing the folder unit 200, the size of the mobile terminal 100 is reduced.

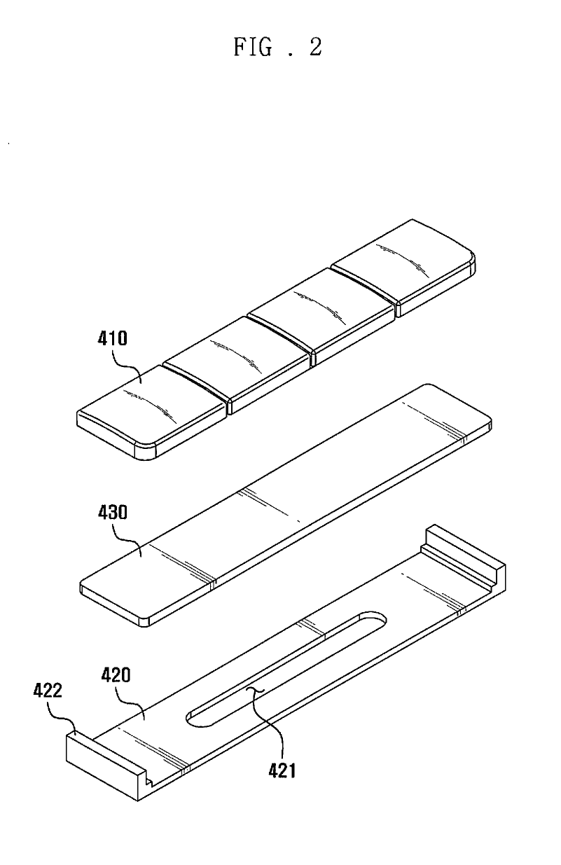

FIG. 2 is a perspective view illustrating the keys 410, a flexible PCB, and a key support of the mobile terminal 100 of FIG. 1.

Referring to FIG. 2, the keys 410 and a flexible PCB 430 are mounted in a key support 420. The keys 410 may be integrally formed in a predetermined quantity. In the present embodiment, four keys are formed in one integral piece, however a different quantity of keys may be formed in one integral piece. Numerals or characters are printed on an upper surface of the keys 410. The flexible PCB 430 is mounted between the keys 410 and the key support 420. In the present embodiment, the flexible PCB 430 is individually formed to correspond to each key support 420, however one flexible PCB 430 may be used for an entire keypad module formed of a plurality of key supports 420.

A coupling hole 421 is formed in the key support 420. The size of the coupling hole 421 is set according to a location of the key support 420. Protrusions 422 for preventing the keys 410 and the flexible PCB 430 from being separated are formed at both ends of the key support 420.

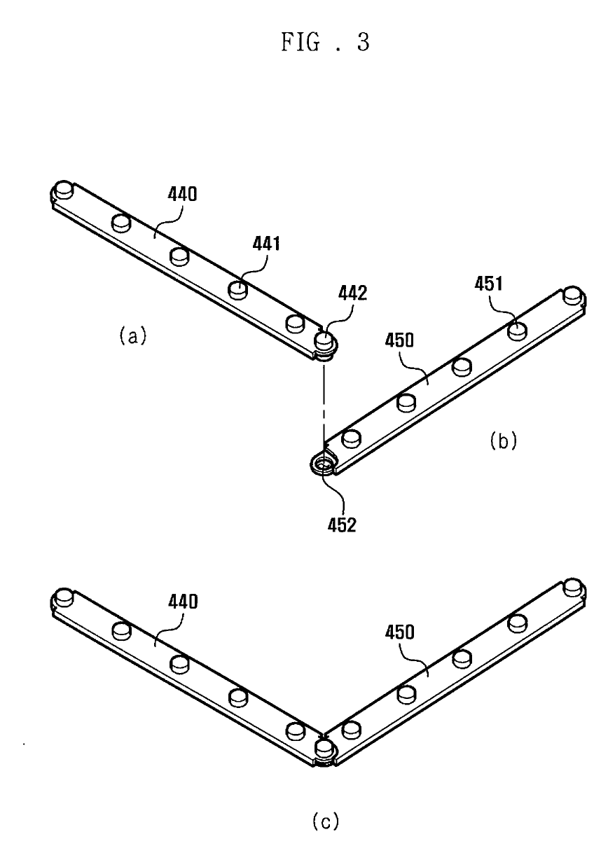

Diagrams (a) and (b) of FIG. 3 are perspective views illustrating links for coupling to the key support 420 of FIG. 2.

Referring to diagrams (a) and (b) of FIG. 3, a first link 440 and a second link 450 have first coupling protrusions 441 and second coupling protrusions 451, respectively. The quantity of the first and second coupling protrusions 441 and 451 is set according to the quantity of the key supports 420 to be connected to the first link 440 and second link 450. When the first link 440 and the second link 450 move, the first and second coupling protrusions 441 and 451 move within the coupling hole 421 formed in the corresponding key support 420. As the first and second coupling protrusions 441 and 451 move, the key supports 420 move.

Referring to diagram (c) of FIG. 3, an end protrusion 442 is formed in the end portion of the first link 440, and an end hole 452 is formed in the end portion of the second link 450. The first link 440 and the second link 450 are connected to each other by inserting the end protrusion 442 of the first link 440 into the end hole 452 of the second link 450.

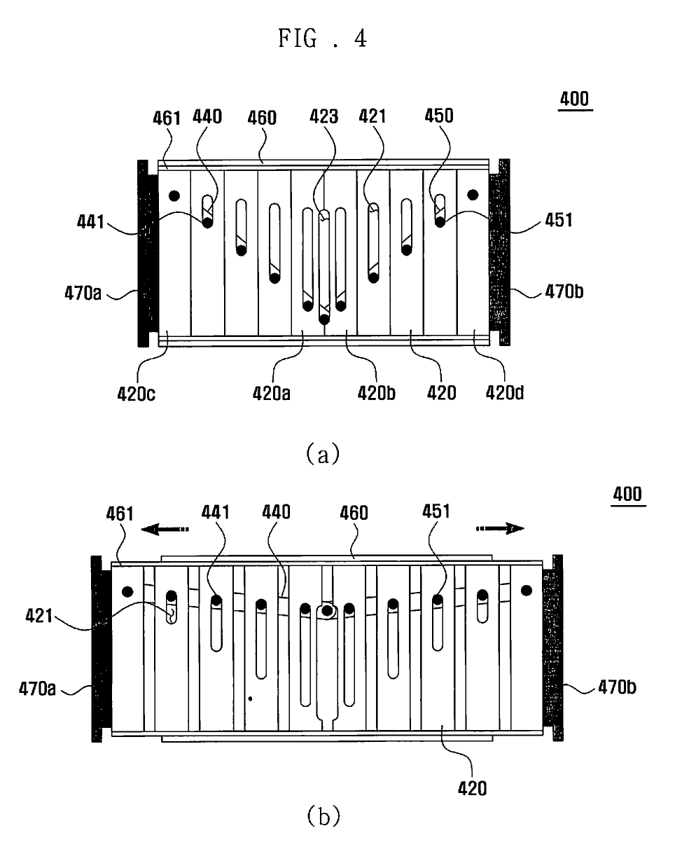

Diagrams (a) and (b) of FIG. 4 are plan views illustrating a keypad module according to another exemplary embodiment of the present invention.

Referring to diagram (a) of FIG. 4, a keypad module 400, according to another embodiment of the present invention, includes the key support 420, a guide unit 460, a first driver 470a, a second driver 470b, the first link 440, and the second link 450. A plurality of the keys 410 (not shown in FIG. 4) are mounted in the key support 420 (e.g. a-d). The guide unit 460 houses a plurality of the key supports 420. The guide unit 460 includes a guide rail 461. The key supports 420 are housed in the guide unit 460 through the guide rail 461. The guide rail 461 extends to the outside of the guide unit 460 and retracts to the inside thereof according to movement of the plurality of key supports 420.

The first driver 470a moves to the inside and the outside of the guide unit 460 at one side of the guide unit 460, that is the first driver 470a slides into and out of the guide unit 460. The second driver 470b moves to the inside and the outside of the guide unit 460 at the opposite side of the guide unit to that at which the first driver 470a moves. The first driver 470a and the second driver 470b are coupled to the moving case 320 of the mobile terminal 100. Therefore, as the moving case 320 moves, the first driver 470a and the second driver 470b move.

In the present embodiment, an even number of the key supports 420 are housed in the guide unit 460. A link groove 423 is formed between two key supports 420a and 420b positioned at the center of the guide unit 460. The first link 440 and the second link 450 are connected within the link groove 423. The coupling hole 421 is formed in each key support 420. The further the coupling hole 421 is positioned from the first driver 470a and the second driver 470b, the greater is the length of the coupling hole 421. That is, the length of the coupling holes 421 formed in the key supports positioned closer to the center of the guide unit 460 (for example, 420a and 420b) is greater than that of the coupling holes 421 formed in the key supports positioned closer to an edge of the guide unit 460 (for example, 420c and 420d).

The key support 420c contacting with the first driver 470a is fixed to the first driver 470a by the corresponding first coupling protrusion 441 formed in the first link 440. The key support 420d contacting with the second driver 470b is fixed to the second driver 470b by the corresponding second coupling protrusion 451 formed in the second link 450. In the present embodiment, by forming the coupling holes 421 formed in the key support 420c contacting with the first driver 470a and in the key support 420d contacting with the second driver 470b to have the same size as the coupling protrusion 441 and 451 formed in the first link 440 and in the second link 450, the key support 420c and the key support 420d are fixed to the first link 440 and the second link 450, respectively. The key support 420c and the key support 420d may be connected to the first link 440 and the second link 450, respectively, using other methods.

The first and second coupling protrusions 441 and 451 formed in the first link 440 and the second link 450, respectively, can move within the coupling holes 421 formed in the key supports 420. By moving the first link 440 and the second link 450, the first and second coupling protrusions 441 and 451 move within the coupling holes 421, and the key supports 420 are moved by the movement of the first and second coupling protrusions 441 and 451.

In order to widen gaps between the keys 410, the user moves the first driver 470a and the second driver 470b in a direction away from the guide unit 460 (in the present embodiment, an arrow direction shown in diagram (b) of FIG. 4. The coupling holes 421 of the key supports 420 are formed in a direction perpendicular to a moving direction of the first driver 470a and the second driver 470b (in the present embodiment, a length direction of the key support 420), however the present invention is not limited to the direction in which the coupling holes are formed. Therefore, as the first driver 470a and the second driver 470b move, the first link 440 and the second link 450 move in a direction perpendicular to the moving direction of the first driver 470a and the second driver 470b. As the first link 440 and the second link 450 move, gaps between the key supports 420 are widened. The gaps between the key supports 420 are widened by extension of the guide rail 461.

The gaps between the key supports 420 are determined by the gaps between the first coupling protrusions 441 and the gaps between the second coupling protrusions 451. Therefore, by uniformly forming the gaps between the first coupling protrusions 441 and the gaps between the second coupling protrusions 451, the gaps between all of the key supports 420 become uniform.

After the user terminates use of the key pad, by moving the first driver 470a and the second driver 470b in a direction towards the guide unit 460, the gaps between the key supports 420 are narrowed.

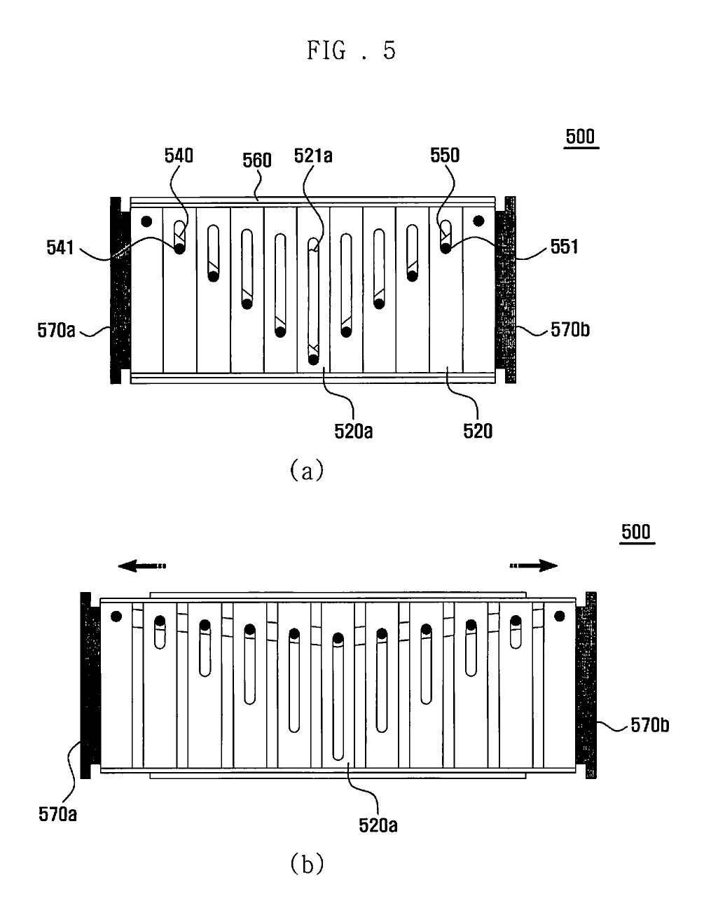

Diagrams (a) and (b) of FIG. 5 are plan views illustrating a keypad module according to another embodiment of the present invention.

Referring to diagram (a) of FIG. 5, according to this embodiment of the present invention, an odd number of key supports 520 are housed in a guide unit 560 of a keypad module 500. A first link 540 and second link 550 are connected within a coupling hole 521a formed in a key support 520a positioned at the center of the guide unit 560. The key support 520a positioned at the center is fixed to the guide unit 560.

In order to widen gaps between the keys 410, the user moves a first driver 570a and a second driver 570b in a direction away from the guide unit 560, as shown in diagram (b) of FIG. 5, similarly to the operation of the keypad module 400 shown in diagram (b) of FIG. 4. However, as shown in diagram (b) of FIG. 5, the key support 520a positioned at the center does not move. Other operations of the keypad module 500 are similar to operations of the keypad module 400 shown in FIG. 4 and therefore a detailed description thereof is omitted.

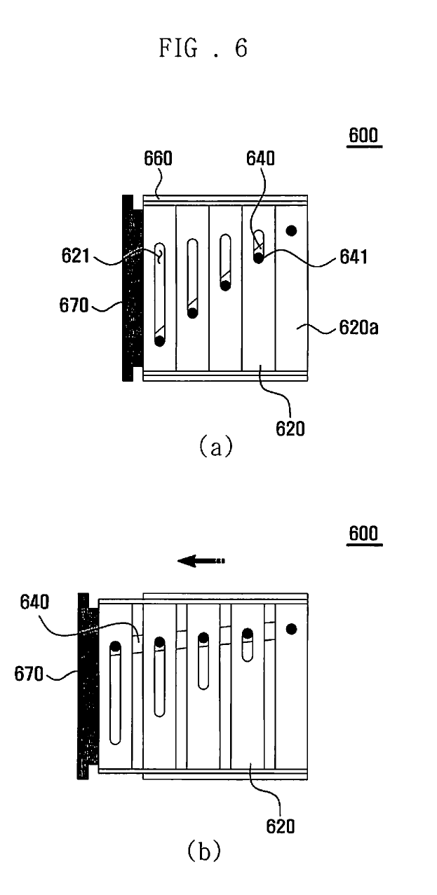

Diagrams (a) and (b) of FIG. 6 are plan views illustrating a keypad module according to another embodiment of the present invention.

Referring to diagrams (a) and (b) of FIG. 6, according to this embodiment 5 of the present invention, a keypad module 600 includes a driver 670 positioned at a side surface thereof. A key support 620a positioned at a side surface of the keypad module 600 opposite to the side surface at which the driver 670 is positioned is fixed to a guide unit 660. A link 640 has one end rotatably connected to the key support 620a and the other end slidably connected to the driver 670. Coupling protrusions 641 are formed in the link 640, and a plurality of key supports 620 are coupled to the link 640 through the coupling protrusions 641.

As the driver 670 moves, the link 640 moves. As the link 640 moves, the coupling protrusions 641 move within the coupling holes 621 formed in the key supports 620, and the key supports 620 are moved accordingly.

In order to widen gaps between the keys 410, the user moves the driver 670 in a direction away from the guide unit 660, as shown in diagram (b) of FIG. 6, whereby the link 640 moves in a direction perpendicular to the moving direction of the driver 670. As the link 640 moves, gaps between the key supports 620 are widened.

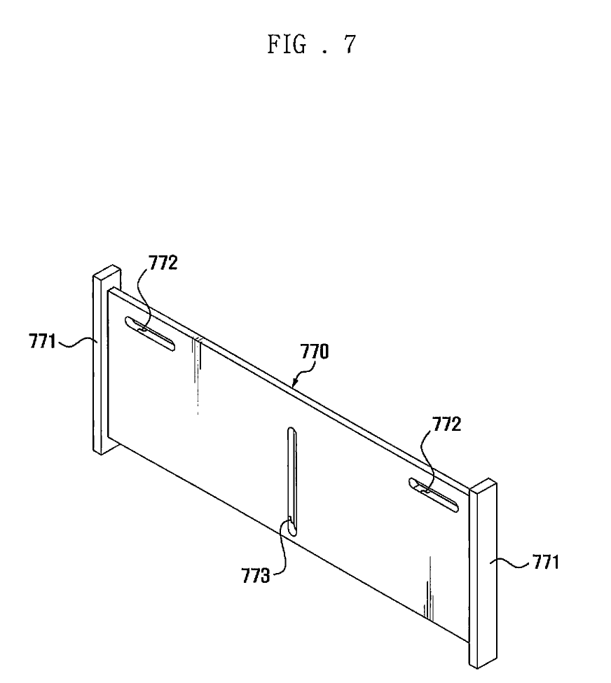

FIG. 7 is a perspective view illustrating a guide panel of a keypad module according to another e embodiment of the present invention.

Referring to FIG. 7, a guide panel 770 has a quadrangular shape, however a shape of the guide panel 770 is not limited thereto. A retention unit 771 is formed at each end of the guide panel 770. The retention unit 771 prevents a key support from being becoming detached. A moving hole 772 is formed adjacent to each end of the guide panel 770 at one side thereof. A link groove 773 is formed at the center of the guide panel 770.

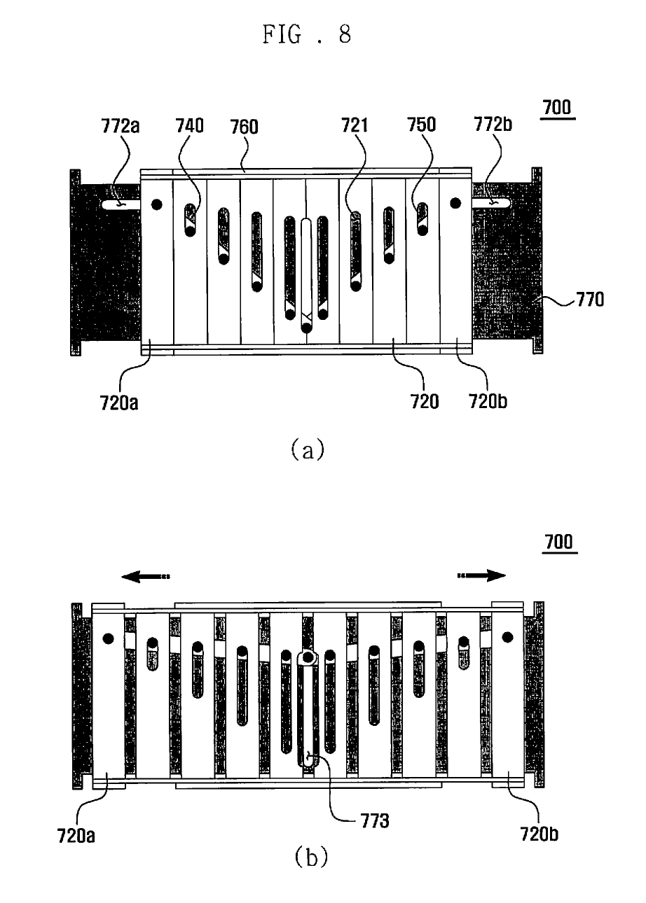

Diagrams (a) and (b) of FIG. 8 are plan views illustrating a keypad module having the guide panel 770 of FIG. 7.

Referring to diagram (a) of FIG. 8, a keypad module 700 includes a key support 720, guide unit 760, guide panel 770, first link 740, and second link 750. A plurality of the key supports 720 are housed in the guide unit 760. The guide panel 770 is fixed to the guide unit 760. The plurality of key supports 720 move on the guide panel 770.

The first link 740 has one end connected to a moving hole 772a formed adjacent to one end of the guide panel 770 at one side thereof. In the present exemplary embodiment, the first link 740 is connected to the moving hole 772a by forming a moving protrusion in the first link 740 and inserting the moving protrusion into the moving hole 772a, however the present invention is not limited thereto. The second link 750 has one end connected to a moving hole 772b formed adjacent to the opposite end of the guide panel 770 at the same side thereof as the moving hole 772a. In the present exemplary embodiment, the second link 750 is connected to the moving hole 772b by forming a moving protrusion in the second link 750 and inserting the moving protrusion into the moving hole 772b, however the present invention is not limited thereto. The moving protrusions of the first link 740 and the second link 750 move along the moving holes 772a and 772b. The first link 740 and the second link 750 are connected to each other at one end to move within the link groove 773 of the guide panel 770. Coupling protrusions are formed in the first link 740 and the second link 750. Coupling holes 721 of the plurality of key supports 720 are connected to the first link 740 and the second link 750 through the coupling protrusions thereof.

Key supports 720a and 720b positioned at the outside of the plurality of key supports 720 are coupled to the ends of the first the link 740 and the second link 750, respectively. Therefore, when the key supports 720a and 720b move, the first link 740 and the second link 750 also move.

In order to widen gaps between the keys, the user moves the key supports 720a and 720b positioned at both sides in a direction away from the guide unit 760, as shown in diagram (b) of FIG. 8. When the keypad module 700 is applied to the mobile terminal 100, the key supports 720a and 720b positioned at the outside of the key supports 720 are connected to the moving case 320 and the user can move the key supports 720a and 720b by moving the moving case 320. As the key supports 720a and 720b move, the first link 740 and the second link 750 move, whereby moving protrusions formed in the first link 740 and the second link 750 move along the moving holes 772a and 772b, respectively. Other operations of the keypad module 700 are similar to operations of the keypad module 400 shown in FIG. 4 and therefore a detailed description thereof is omitted.

The mobile terminal according to an embodiment of the present invention may be any portable electronic device, such as a mobile phone, personal digital assistant (PDA), navigation device, digital broadcasting receiver, and portable multimedia player (PMP).

As described above, when using a mobile terminal according to the present invention, gaps between keys provided in the mobile terminal can be widened uniformly. Therefore, a user can conveniently use keys provided in the mobile terminal.

Although embodiments of the present invention have been described in detail hereinabove, it should be clearly understood that many variations and modifications of the basic inventive concepts herein described, which may appear to those skilled in the art, will still fall within the spirit and scope of the exemplary embodiments of the present invention as defined in the appended claims.

What is claimed is:

1. A keypad module, comprising:
a plurality of key supports for mounting keys;
a guide unit for housing the plurality of key supports;
a driver for sliding into and out of the guide unit at one side of the guide unit; and
a link for connecting the driver and the plurality of key supports,
wherein gaps between the plurality of key supports are changed by movement of the driver.

2. The keypad module of claim 1, wherein a guide rail is formed in the guide unit, and
the guide rail extends and retracts according to movement of the plurality of key supports.

3. The keypad module of claim 1, wherein a coupling hole is formed in each of the plurality of key supports, and
a plurality of coupling protrusions are formed on the link, each coupling protrusion moving within one of the coupling holes for moving the plurality of key supports.

4. The keypad module of claim 3, wherein one of the key supports contacts with the driver and is fixed thereto through the coupling protrusion connected to the key support.

5. The keypad module of claim 4, wherein in the plurality of key supports, the closer the key support is positioned to the driver, the smaller the length of the corresponding coupling hole.

6. The keypad module of claim 1, further comprising Light-Emitting Diodes (LEDs) illuminate to the outside through the gaps when the gaps between the plurality of key supports are widened by the movement of the driver.

7. A keypad module, comprising:
a plurality of key supports for mounting keys;
a guide unit for housing the plurality of key supports;
a first driver for sliding into and out of the guide unit at a first side of the guide unit;
a second driver for sliding into and out of the guide unit at a second side of the guide unit opposite to the first side;
a first link for connecting the first driver and at least one of the plurality of key supports; and
a second link for connecting the second driver and the key supports not connected with the first link,
wherein gaps between the plurality of key supports are changed by movement of the first driver and the second driver.

8. The keypad module of claim 7, wherein a guide rail is formed in the guide unit, and
the guide rail extends and retracts according to movement of the plurality of key supports.

9. The keypad module of claim 7, wherein the first link and the second link are connected to each other at one end.

10. The keypad module of claim 9, wherein a coupling hole is formed in each of the plurality of key supports, and
a plurality of coupling protrusions are formed on the first link and the second link, each coupling protrusion moving within one of the coupling holes for moving the plurality of key supports.

11. The keypad module of claim 10, wherein one of the key supports contacts with the first driver and is fixed thereto through the coupling protrusion connected to the key support, and another of the key supports contacts with the second driver and is fixed thereto through the coupling protrusion connected to the another key support.

12. The keypad module of claim 11, wherein when the plurality of key supports are an odd number, the key support positioned at the center of the guide unit is fixed to the guide unit, and
the first link and the second link are connected at a coupling hole of the fixed key support.

13. The keypad module of claim 11, wherein when the plurality of key supports are an even number, a link groove is formed at the edges of two adjacent key supports positioned at the center of the guide unit, and
the first link and the second link are connected at the link groove.

14. The keypad module of claim 7, further comprising Light-Emitting Diodes (LEDs) illuminate to the outside through the gaps when the gaps between the plurality of key supports are widened.

15. A keypad module, comprising:
a plurality of key supports for housing keys, each key support having a coupling hole;
a guide unit for housing the plurality of key supports;
a guide panel fixed to the guide unit and having moving holes at opposite ends;
a first link having one end connected to the moving hole formed at one end of the guide panel and connected to a coupling hole of at least one of the plurality of key supports through a coupling protrusion formed on the first link; and
a second link having one end connected to the moving hole formed at the end of the guide panel opposite to the end connected to the first link, and the other end connected to the first link, and connected to a coupling hole of the key supports not connected with the first link through a coupling protrusion formed on the second link,
wherein the plurality of key supports move on the guide panel.

16. The keypad module of claim 15, wherein the guide panel has a link groove at the center thereof, and
the first link and the second link are connected at the link groove.

17. A mobile terminal, comprising:
a keypad module, comprising;
a plurality of key supports for mounting keys;
a guide unit for housing the plurality of key supports;
a driver for sliding into and out of the guide unit at one side of the guide unit; and
a link for connecting the driver and the plurality of key supports;
a fixed case for mounting the guide unit; and
a moving case movably coupled to the fixed case for enclosing the outside of the driver,
wherein gaps between the plurality of key supports are changed by movement of the moving case.

18. A mobile terminal, comprising:
a keypad module, comprising
a plurality of key supports for mounting keys;
a guide unit for housing the plurality of key supports;
a first driver for sliding into and out of the guide unit at a first side of the guide unit;
a second driver for sliding into and out of the guide unit at a second side of the guide unit opposite to the first side;
a first link for connecting the first driver and at least one of the plurality of key supports; and
a second link for connecting the second driver and the key supports not connected with the first link;
a fixed case for mounting the guide unit; and
a first moving case and a second moving case movably coupled to the fixed case for enclosing the outside of the first driver and the second driver, respectively,
wherein gaps between the plurality of key supports are changed by movement of the first moving case and the second moving case.
